(19) United States
(12) Patent Application Publication
(10) Pub. No.: US 2018/0212087 A1
(43) Pub. Date: Jul. 26, 2018

(54) MOBILE POWER SYSTEM

(71) Applicant: Renovagen Ltd., London (GB)

(72) Inventor: John Hingley, London (GB)

(21) Appl. No.: 15/849,444

(22) Filed: Dec. 20, 2017

Related U.S. Application Data
(63) Continuation of application No. 14/092,458, filed on Nov. 27, 2013, now abandoned.

(30) Foreign Application Priority Data
Feb. 20, 2013 (GB) 1302961.6
Nov. 13, 2013 (GB) 1320055.5

(51) Int. Cl. H01L 31/04; H02S 20/00; H02S 30/20; H02S 30/00; F24S 40/10; H01L 31/048; H02S 40/38

(52) U.S. Cl. CPC H01L 31/04; H02S 20/00; H02S 30/20; H02S 30/00; Y02E 10/50; H01L 31/048; H02S 40/38; Y02E 10/40; F24S 40/10

(57) ABSTRACT

A mobile power plant comprising a retractable flexible solar array structure comprising a plurality of thin film photovoltaic modules mounted on a flexible substrate; a spool attached to a portion of the flexible solar array structure and around which the flexible solar array structure can be rolled; power cabling integrated into the flexible solar array structure for transmitting power from the plurality of photovoltaic modules to the spool-end of the flexible solar array structure; a transportable container in which the spool is mounted, the transportable container being capable of housing the flexible solar array structure when it is in a rolled configuration.

### FIELD OF THE INVENTION

The invention relates to mobile power systems, especially solar mobile power plants that generate larger amounts of power (i.e. of the order of several kW, or multi-kW) from photovoltaic panels housed in a transportable structure.

### BACKGROUND

The importance of the mobilisation of solar power plants has increased in recent years for a number of reasons. For example, military demand for reducing expensive fuel consumption at Forward Operating Bases (FOBs) has increased. At these locations, it may cost 10 to 100 times the normal cost of diesel to deliver fuel and there is often a need to provide a more secure energy source. As a further example, Government demand for mobile power plants for disaster emergency relief in the wake of natural disasters such as hurricanes, earthquakes and tsunamis in locations such as the US and Japan is higher. There have also been recent Government and social drives, for legal and ethical reasons, to reduce greenhouse gas emissions in order to reduce climate change. Further, the dramatic reduction in costs of solar cells and other components related to solar photovoltaic (PV) systems has opened up many more opportunities to be competitive in the market with such a solution. In another example, the boom in telecommunications in off-grid locations across the world has led to a demand for renewable power plants in order to eliminate the high costs of fuelling diesel generators at these locations.

These factors, at least, have influenced a number of attempts to produce a solution which provides meaningful amounts of power from a transportable package. In general, present solutions suffer from one or both of at least two problems. The first is low power output; typically between 1 kilowatt-peak (kWp) and 16 or 28 kWp is produced. The second is long deployment time as a result of the number of complexities and the manual effort in deploying a large array of panels that have been stacked in a transportable-sized structure. The latter is a problem particularly in the military where immediate access to power may be essential for mission-critical equipment required to secure a location. Therefore, a deployment time of just a few minutes is desirable.

The power output remains a major limitation to the market for most of the known products. A solution producing 8 kWp, for example, would have no appreciable impact on, for example, the total power requirements of a large military FOB (which may be of the order of multi-MW), nor would it be able to compete against diesel gensets (which can suitably be of the order of 100 kW).

A number of different types of solar panel are available. Monocrystalline silicon cells are rigid panels typically made from single-crystal wafers cut from cylindrical silicon ingots and are highly efficient. Polycrystalline silicon PV cells are rigid panels typically made from cast square ingots, and are typically cheaper than—but not quite as efficient as—monocrystalline cells. Thin-film PV cells are also available. There are a range of materials that may be used in thin-film panels, which are lightweight and flexible compared to the monocrystalline and polycrystalline silicon counterparts. Examples of such materials include amorphous silicon, cadmium telluride (CdTe), copper indium gallium selenide (CIGS), gallium arsenide (GaAs) and organic solar cells such as dye-sensitized solar cells.

The problems with thin-film solar panels are that they are typically half as efficient as monocrystalline or polycrystalline panels and typically twice as expensive. Accordingly, thin film panels are disclosed for small-scale uses, for example in personal electronics chargers or for building-integrated applications. For example, US2011017262 discloses a portable solar charger with flexible thin-film panels, and US2012073624 discloses an awning-type solar protection device.

There are a number of examples of existing large-scale mobile solar power concepts, all of which use rigid monocrystalline or polycrystalline solar panels.

US2012080072 discloses a container-based system which includes panels stored stacked together inside the container, which must then be removed manually and attached to the mounting mechanism on the container. ‘The associated “Scorpion Energy Hunter” product has a stated deployment time of 90 minutes. The power generation capacity of that product is not stated, but a top-end estimate based on the 8 panels producing 250 Wp each is 1 kWp. This concept therefore suffers from both low power generation and relatively long deployment time.

US2011146751 discloses a container-based system with panels that pivot between stowed and deployed positions, The associated “Ecos Lifelink” product claims to produce 16 kWp of power from two 20 ft (6.1 m) containers. The stowing mechanism of that product is rather complex with many moving parts and it is likely that it would take a significant amount of manual effort and time to deploy.

U.S. Pat. No. 8,254,090 discloses a container-based system consisting of both solar panels and a wind turbine. The solar panels are stored stacked together in the container, and must be manually removed and fixed to included collapsible frames and connected by hand, separate from the container itself. The associated “Power Pods” product is from Sundial SmartPower. Whilst it achieves a much higher power generation capacity (up to 28 kWp), it suffers greatly due to the length of time it would take to deploy (from 8 hours down to 4 hours for those trained in the assembly).

WO2012170988 discloses a trailer-based solution with a scissor arm mechanism for deploying the panels. Whilst the power generation capacity is not stated, the illustrations show only 8 panels. This is likely due to the structural limitations of the mechanism, so this concept, whilst quick to deploy, could probably only generate around 2 kWp.

US2012206087 discloses another trailer-based solution, with a range of associated products named “DC Solar Solutions”. The deployment is via a simple rotation mechanism, but the power generation is limited to 2.4 kWp.

Similar concepts to the above have also been described in US 2012/0293111, WO2012090191 and WO2012134400. All of these solutions utilise traditional rigid monocrystalline or polycrystalline solar panels which are currently the most cost-effective solution on a per-watt basis. In doing so, they all strike some compromise between deployment speed/portability and power generation capacity.

US 2012/0090659 describes another example of a portable solar panel array having a series of solar panels that are coupled to one another and can be transformed from an expanded configuration to a collapsed configuration, for example by folding or rolling. Connectors are provided to removably electrically connect the plurality of solar panels together.

There remains a need for large mobile solar power units having a high level of power output, whilst retaining portability and quick deployment capability.

### SUMMARY OF THE INVENTION

The present invention describes a mobile power system for simultaneous high power generation and fast deployment. The mobile solar power generator apparatus of the invention is particularly suited as a mobile power plant or mobile power station.

The present invention relates to a retractable flexible solar array structure, comprising an array of photovoltaic modules mounted on a flexible support substrate, that can be stored in a rolled configuration. Each module of the solar array structure (that might also be termed a “flexible panel structure”) includes one or more flexible panels of thin-film PV material on the flexible support substrate. The PV panels may all be mounted on the same side of the substrate. In some examples, the panels comprise a flexible carrier substrate on which the thin PV film is deposited, the panels (including the PV film and carrier substrate) being mounted on the support substrate of the flexible array structure. In other examples, the flexible panel carrier substrate and support substrate of the flexible array structure are the same.

The flexible array structure is supported on a spool within a transportable container. In some examples the transportable container is an ISO standard shipping container. The container dimensions (l×w×h) may be 2.4 m×2.2 m×2.3 m (8 ft×7 ft 1″×7 ft 5″) or 3.0 m×2.4 m×2.6 m (10 ft×8 ft×8 ft 6″) or 3.0 m×2.4 m×2.9 m (10 ft×8 ft×9 ft 6″) or 6.1 m×2.4 m×2.6 m (20 ft×8 ft×8 ft 6″) or 6.1 m×2.4 m×2.9 m (20 ft×8 ft×9 ft 6″) or 9.1 m×2.4 m×2.6 m (30 ft×8 ft×8 ft 6″) or 9.1 in×2.4 m×2.9 m (30 ft×8 ft×9 ft 9″) or 12.2 m×2.4 m×2.6 m (40 ft×8 ft×8 ft 6″) or 12.2 in×2.4 m×2.9 m (40 ft×8 ft×9 ft 6″).

A preferred ISO standard shipping container configuration is a side-opening “Full Side Access” shipping container having doors which open the full length of the long side of the container because this provides an opening for the widest possible roll to be deployed from an unmodified container. A preferred ISO standard shipping container length is the 20 ft version, because this is the standard size used for transportation of military supplies by many military forces, for which handling and transportation equipment and infrastructure already exists.

In other examples, a modified end-door-access container may be used by cutting a longitudinal access slit in the container wall for the array structure to be deployed through. In such examples it is possible that additional structural reinforcement of the container and re-certification for shipping may be required.

In other examples, the container may be mounted on wheels or take the form of an enclosed trailer.

Due to the thin profile and light weight of the modules/panels, a much larger area of solar panels can be stored within the container than with other panel types. For example, the length of the solar array structure may be as much as 50 m, 100 m, 150 m or even 200 m or more. Hence, a much higher level of power generation can be achieved; for example, 100 kWp to 200 kWp or more for a 12.2 m (40 ft) container. Furthermore, fast deployment is possible with a spool as the spool can be unrolled within minutes; for example, within 5 minutes with vehicle-tow assisted unrolling for those trained in the process.

The mobile power plant of the present invention may also have a battery bank and charge controllers for energy storage. In this way, the power plant may be able to run overnight or at other times when the solar radiation is not sufficient for providing the desired output.

The mobile power plant of the invention may also have an inverter, preferably a solar inverter, to convert the DC output of the PV panels and output AC power. The solar inverter may have a maximum power point tracking feature. The AC inverter may be grid-synchronous.

The array structure may include a flexible substrate (on which the PV panels are mounted) that has a laminated or layered structure. One or more of the layers may be a tension-bearing substrate layer. A tension-bearing substrate layer may be capable of withstanding much or all of the tensile stress imposed on the array structure. The tensile forces on the array structure may be very high when an unrolling force is applied or during wind-loading conditions, which may in turn damage the solar panels (which are not intended to carry such loads). Accordingly, the panels may be protected from damage by the tension-bearing substrate layer. Examples of suitable materials for a tension-bearing substrate layer may include one or more of an aramid fibre such as Kevlar®, a polyester such as polyester terephthalate (PET) or polyethylene naphthalate (PEN) including woven polyester fabrics, a carbon fibre woven fabric, a liquid-crystal polymer such as Vectran®, nylon, and cotton “canvas” or flax materials. The material chosen may be coated with a protective coating—for example a PVC/vinyl coating—in order to provide waterproofing and environmental protection.

The tension-bearing layer may be arranged in any order within the laminated/layered structure—but may advantageously be positioned on, or close to, the lower surface of the structure (i.e. the side which must conform to a reduced radius when the array structure is rolled), when a material of sufficient elasticity may be used. This arrangement is advantageous if such a material is pre-tensioned (to an appropriate amount) before the layers are bonded together, so that there is an inherent tension present in the bonded array structure on its lower side. This approach causes the array structure to naturally form into a curved shape through compression of the lower surface and without extension/tension of the upper surface. This is advantageous in order to create acceptable rolling behaviour which prevents tensile strain being transmitted to the solar modules/panels, which could cause damage when the array structure is rolled. The degree of pre-tension can be selected (e.g. through experimentation) to ensure that the array structure will still lay flat under its own weight or with a small amount of longitudinal tension applied. For example, with a smallest curvature radius required of 0.25 m and an array structure thickness of 8 mm, then around 3.2% (5 cm per revolution) of compression of the lower surface is required in order for the upper surface not to stretch. Applying between 50% and 100% of this calculated compression as a pre-tensioned elastic strain in the tension-bearing layer may be advantageous for optimum results, although other pre-tension strain amounts may also be used.

A secondary benefit of this pre-tensioning approach is that it may help to ensure that the strain incurred by the array structure due to the tensile forces transmitted through the tension-bearing layer during usage (rolling, unrolling, fixing or wind loading) are kept to a minimum—because it may eliminate or reduce the possibility of inherent “slack” in the tensile layer and reduce or eliminate subsequent creep of the material by completing any creep phase prior to bonding the array structure together.

The mobile power plant described herein may include power cabling. The power cabling may be integrated into the flexible array structure. In some examples, the power cabling may be integrated into one or more layers of the substrate of the flexible array structure. In some examples, the array structure may include a layer of filler material, with which the power cabling may be integrated. Examples of suitable filler material may include one or more of a flexible adhesive, rubber or foam rubber, and polyurethane foam. Use of a flexible adhesive for the filler layer may be advantageous, as it provides both bonding and space-filling properties in one material. It may be advantageous to use a low-modulus adhesive which is elastic and compressible, so that it can conform to the strains applied across the filler layer during rolling. An example of such an adhesive may be a modified silane polymer adhesive.

Such arrangements for the power cabling may avoid the potentially long length (often in excess of 100 m) of the array structure affecting the speed of deployment, by having to separately unroll a long length of power cabling and then connecting it at several points along the length of the flexible array structure. This power cabling may be used to transmit the generated power back to the charge controllers and/or inverter once the flexible array structure is deployed. In some examples, the charge controllers and/or inverter are housed in the container. In such cases, the power generated is transmitted to the container.

Whilst the most electrically efficient solution would be to have just a few larger diameter power cables running longitudinally through the array structure, it may on the other hand be advantageous to have many smaller diameter cables running parallel to each other—to the extent that a “ribbon cable” type configuration may be considered. This configuration has a number of advantages for the end product.

Firstly, it enables the array structure to be manufactured with a lower overall thickness, which reduces the magnitude of the rolling strain effects on the array structure as discussed earlier.

Secondly, it means that each PV string (i.e. series connected set of modules) of the array structure, consisting of one or more (but typically a small number, e.g. 2 to 3) of the PV modules, may be separately connected back to the container with their own dedicated power cables. This enables a modularised array to be created in which each string may be individually monitored, controlled and/or disconnected if necessary. Such an array configuration may be much more resilient to variations in performance (such as shading or deployed angle/slope) than an array in which all strings are paralleled together some distance away from any controlling electronics. For example, individual strings or sections (consisting of a small number of strings in parallel) may be connected to their own Maximum Power Point Tracking inverters or charge controllers which optimise the power output for the particular conditions to which that array string/section are exposed. It also means that if the array structure is partially unrolled, the sections of the array which are exposed may still perform optimally.

Thirdly, it provides a level of redundancy in power transmission if the array is damaged or if components fail over time. In the military scenario this may be particularly important to improve the capability of the array to continue generating some power if damaged by enemy fire.

An example of a feasible configuration is the use of 2.5 mm² 1000 VDC certified PV cable embedded at 1 cm spacing. Such a configuration would have a power carrying capacity of at least 10 kW per metre width of a 100 m length array structure at an operating string voltage of 124V—or more at higher voltages—sufficient for the scale of the proposed invention.

In some examples, an “AC-coupled” approach may be applied to the architecture of the electrical system (i.e. interconnectivity of solar array, inverters, battery bank, and charge controllers). This approach involves first converting the DC power from the solar array, via an array-side inverter, into AC delivered onto an AC bus to which all electrical components, including loads, are connected. Electrical power may be consumed by the loads directly, but inverter/chargers then convert any excess AC power hack to DC for charging the battery bank.

In some examples, multiple array-side inverters may be used. In some examples, multiple inverter/chargers may be used, each connected to its own separate battery bank module. In some examples, one of the inverter/chargers may act as a master unit, controlling the power balance on the AC bus and instructing the other inverters to increase or reduce their power output in order to ensure power delivery onto the AC bus is equal to demand. Such an approach may be advantageous because it helps to facilitate modularisation of both the solar array and the battery bank, which improves the resilience, scalability and maintainability of the system.

Whilst additional losses may be incurred through the extra AC-DC-AC conversion (through the battery bank) of the portion of the power not consumable immediately, these losses may be partially or fully compensated for by improved performance of the solar array when this configuration is utilised. In particular, it enables the use of commercially available grid-sync inverters operating at much higher string voltages (up to 750 Voc open circuit or more) for use as the array-side inverters, rather than DC MPPT charger controllers which typically are only available with up to 180 Voc capacity (typically resulting in max operating voltages of around 130V or less)—the higher operating voltage of the former would result in lower transmission losses in the power cabling. Because transmission losses and the feasible thickness of the power cabling are a key limitation to the achievable scale of the rollable solar array of the present invention, enabling higher string voltages in this way may have a significantly advantageous impact on the size of array which can be deployed from a certain container and/or of the efficiency of the system.

In some examples, joints between the cables may be made using a “butt splice” crimp joint or soldered “butt splice” crimp joint. In some examples, such joints may be insulated and sealed using shrink tubing lined with hot-melt adhesive. Such a solution for cable joints is advantageous as it typically creates a joint of a very small size—similar in diameter or only slightly thicker than the cable itself and is short in length and so has negligible impact on rolling of the array structure. Other advantages may include—a high pull-out strength, resilience to flexing incurred during rolling, water-resistance or waterproofing, sufficient insulation for high voltages and low resistance (typically lower than an equivalent length of the cable itself) so that no additional electrical losses are incurred.

In some examples, the spool may be hollow. In some examples, the power cabling may be fed within the centre of the hollow spool.

In some examples, PV combiner boxes or junction boxes may be located within the hollow space of the spool in order to connect strings associated with the same section in parallel and reduce the total number of cables required to exit the spool ends. In some examples, the combiner box or junction box used for this purpose may have external controls to enable individual strings to be automatically disconnected—for example via remote, electronic or computer control.

The power cabling may have retractable connectors at the spool ends which only form a complete connection once the array structure is deployed. In this way, the problem arising from having integrated power cabling that is connected at one end to a fixed power cabling at the container and at another end being connected to a spool that rotates during operation, may be avoided.

The flexible array structure may advantageously be protected from damage when laid on the ground by provision of a layer of protective backing material. Examples of suitable backing material may include one or more of an aramid fibre such as Kevlar® fabric, a nylon such as Cordura® ballistic fabric, and ultra-high molecular weight polyethylene (UHMWPE). In some examples, this layer may be bonded directly to the tension-bearing layer. In other examples, a material may be selected for the tension-bearing layer with properties sufficient to perform the function of both tension-bearing and puncture/tear protection.

The flexible array structure may advantageously be protected from environmental damage by use of an environmental sealing coating. In particular, water-proofing may prevent rain water or moisture from entering the flexible array structure. In some examples, the environmental sealing coating may be applied over the whole of the flexible array structure.

The mobile power plant may have feeder arms with rollers or “leader” slots (a term used to describe a slot through which an expanded cross-section—such as a flexible pole bonded to the tensile fabric—of a tensile fabric may slide in order to provide fixing along one edge of the fabric) which grip the edges of the array structure and ensure it rolls evenly back onto the spool. In this way, the creation of undesirable kinks or folds in the array structure as it is retracted onto the spool may be avoided.

In some examples, the rollers or slots may be fixed directly to the frame which supports the spool. In some examples, a series of more than one slot or a combination of rollers and slots may be mounted on arms extending from the frame or container. In some examples, the bracket or expanded cross-section used to grip the array structure may be triangular or wedge-shaped in order to provide surfaces on which rollers can provide a lateral gripping force. In other examples, the cross-section may be circular. Other cross-section shapes are also possible.

A retractable protective screen which may shield any exposed components within the container when the array structure is deployed may be used. This screen may avoid damage caused by one or more environmental factors such as rain, wind and sand. Examples of suitable materials for the protective screen may include one or more of PVC coated woven cotton canvas, polyester and nylon. Various screen configurations may be used. In one example, two spring-loaded retractable rolls may be provided along the floor and ceiling of an openable edge of the container. In a deployed configuration, the rolls may be fixed to side edges of the container and may also be fixed to upper and lower sides of the deployed array structure (and may be fixed to each other at locations along the container beyond the array structure). Fixing means may include zippers or Velcro® for example. In another example, the container may have doors capable of being split into upper and lower doors with a horizontal gap between them. Each door may have additional flaps capable of sealing against each other or against the deployed array structure. The flaps may be made of steel or fabric with appropriate fasteners and/or seals.

In some examples, the screen or flaps may also have a brush or sweeper edge. The brush may be attached to the lower part of the screen or flaps when deployed. That is, the brush or sweeper edge may be attached to the face closest to the flexible array structure. When the screen is left in place during retraction of the flexible array structure, it may advantageously clean and remove attached dirt or debris from the lower side (the side nearest the ground) of the flexible array structure.

The spool may be motorised. There may be a control system associated with the motorisation for operation by a user or automated control by an electronic or computerised system. This may be advantageous when the forces involved in deployment and retraction are too great for manual operation.

The mobile power plant may have retractable high power DC connectors. The connectors may be located between the rotating spool and the charge controllers. This advantageously enables the power cabling received at the rotating spool to be connected to fixed power cables that connect to the charge controllers and/or inverter.

In some cases it may be desirable to integrate the mobile power plant into a wider area grid or “micro-grid”. This may be achieved in a number of ways. In some examples, the mobile power plant has an AC inverter which is grid-synchronous. In some examples, the mobile power plant has a power connection configured to and capable of receiving power from an external source to charge the battery bank of the mobile power plant. In some examples, the mobile power plant has an electronics system that controls and/or limits the charge state and power output. In some examples, the mobile power plant has a telecommunications system configured to receive control commands and pass them to the electronic control system and to communicate data regarding important properties such as charge state and power output to remote operators or systems. The control and/or limitation may be carried out remotely by a human operator or computer system. Each of the above may be capable of being implemented as required by an existing “smart-grid” control system or “smart grid” industry standard. The above may be present alone or in combination.

There may be provided an additional power source and/or additional energy storage methods. Examples of suitable additional power sources may include at least one of one or more diesel generators or one or more fuel cells. An example of an additional energy storage module is a hydrogen electrolyser generator. In some examples, a hydrogen electrolyser generator may have one or more connected hydrogen storage tanks. This additional power source may act as a secondary backup power source.

There may be included a set of support poles and guy ropes for raising one side edge of the array structure once deployed, in order to incline it towards the sun or other appropriate or specified angle. This is appropriate for use when the system will be deployed for long enough such that the percentage gains sufficiently offset the additional manual deployment effort, and has the advantage that the panels may be kept at an optimum angle relative to the sun for maximum power output, especially when the system is used at higher latitudes.

In some embodiments an inflatable support frame is used as an alternative to the support pole/guy rope system described above. The inflatable frame is configured to have a top surface along which the solar array structure can extend when deployed. The inflatable support frame may itself be rollable when deflated. It may conveniently be secured to the ground by pegs once deployed to secure it in place. This approach may be advantageous in order to improve wind-loading behaviour, dust/sand shedding, water drainage and speed of deployment.

In some examples the inflatable frame may be separately unrolled from a separate spool within the same or a different container to the solar array structure. In other examples, the frame may be rolled on the same spool as the array structure. In such cases, the inflatable frame may be integrated onto the lower side of the array structure. This may be the preferred approach for simplicity and fastest deployment of the array.

In some examples, the inflatable frame may comprise a series of separate chambers. These chambers may be spaced from one another along the length of the solar array structure, with gaps between them. This approach may be advantageous as it improves resilience against damage (for example, if one chamber is punctured, the whole frame will not deflate and the array will continue to be supported) and (in the case where the chambers are spaced apart) can improve airflow through, around and underneath the array which improves cooling of the array and so is advantageous for PV performance and longevity.

In some examples, inflation and deflation of the inflatable frame may be effected by an air pump, which may for example be powered by the mobile power system itself. In some examples, transmission of air pressure to the inflatable chambers may be achieved by interconnecting them via compact isolation valves within or underneath the array structure. The valves may be open during deployment and then closed in order to isolate each chamber during usage. In other examples, transmission of air pressure to the inflatable frame chambers may be achieved via pneumatic lines embedded within the array structure, in a way similar to which the power cabling may be embedded—for example, by replacing some of the power cables which are not required with pneumatic lines of the same diameter—or by fitting pneumatic lines in gaps between power cables. In this way, the air pressure in each chamber can be separately monitored and controlled using automatic pumps and valves in the container, with no external manual air connection or manual valve control required, which is advantageous for the fastest possible deployment and inflation.

There may additionally be fluid-filled cooling lines integrated into the array structure—in place of some of the power cables or between them. Coolant fluid contained in the lines may be circulated by a pump to an atmospheric heat sink or heat exchanger for example. A refrigeration circuit may be used to improve the rate of heat extraction. This may be advantageous in order to reduce the temperature of the PV array surface, which improves power output, efficiency and longevity of the PV modules. This may be particularly advantageous for desert deployment, where surface black-body temperatures may approach 70-80 degrees Celsius or more, which is close to the limits to which many PV modules are certified.

The rollable array may alternatively be deployed on top of specific convenient structures. An example may be on top of military base bastion walls—which typically may consist of fabric and wire-mesh cubic boxes (or “gabions”) filled with sand, earth or rubble. The common box in use is the “HESCO” bastion box.

Deployment on the top of the HESCO bastion box walls may be advantageous because space for large PV arrays may be difficult to find or create on military bases—particularly on small Forward Operating Bases. The space on top of the HESCO bastion walls is not used for other purposes, and being raised off the ground would afford improved ventilation and prevent damage by foot traffic or vehicles.

For certain sizes of base and bastion configurations it may be possible for up to 100% of the base power requirements to be supplied from the surface area of the tops of the bastion walls, if fully covered in PV modules. In this scenario, the solar array structure width may be selected to match the width of the HESCO bastion walls—for example 1 metre or 2 metres in width. Due to the narrower width than conceived of in a 20 ft or 40 ft ISO container version, in this scenario it may be more appropriate to select a 10 ft ISO container.

An attachment means is required to fix the array down to the bastion. In some examples, separate clips may be used which are manually attached at regular intervals to the bracket or “kader” pole and pulled down to clip onto the HESCO box wire mesh. In other examples, such clips may be attached to the edges of the flexible array structure at regular intervals, in order to facilitate faster fixing. In other examples, the bastion boxes may be modified to include a “kader” slot or channel on extended top side edges of the bastion boxes—to either form a continuous slot, or sections at regular intervals. This allows the flexible solar array to slide directly into the slots as it is unrolled, providing the fastest possible fixing. Such a solution may be most advantageous as the array is fixed as it is deployed - offering the potential to deploy the array even in strong winds (which would be difficult to achieve safely in configurations where manual fixing is required after deployment).

In some examples, the inflatable frame may be used in combination with the “HESCO” bastion box “kader” slot attachment. This approach may be advantageous because it automatically tensions the array structure against the HESCO boxes as the inflatable frame is inflated, eliminating any need to use manual tensioning clips.

The mobile power plant may be protected against electromagnetic pulse (EMP) attack or lightning strike. In some examples, this protection is provided by a mesh screen that forms a Faraday cage around the container. The mesh screen may comprise copper wire. In some examples, the Faraday cage is attached to the walls of the container. In some examples, the Faraday cage is attached to the weather-protective screen. In some examples, protection is provided by surge protectors. The surge protectors may be located where the power cabling coming from the array structure meets. The surge protectors advantageously isolate any incoming surge that has been created in the array structure and protect the components in the container. In some examples, protection is provided by both the mesh screen and the surge protectors.

In some examples, the mobile power plant is armoured. In some examples, only the container is armoured. Such armour may be suitable to provide protection against threats including small arms fire, rocket propelled grenades (RPGs), improvised explosive devices (IEDs) or similar. Examples of suitable materials for the armour may include one or more of hardened steel plate, polyethylene composite armour, ballistic nylon or Kevlar®.

Some or all of the above features may be combined. Such a mobile solar power plant is superior in both power output and deployment speed than that of the existing systems.

### BRIEF DESCRIPTION OF THE FIGURES

FIG. 1 is a perspective view of an embodiment of the mobile power plant of the invention in a deployed position.

FIG. 2 is a perspective view of an embodiment of the mobile power plant of the invention in a stowed position.

FIG. 3 shows an embodiment of an outline electrical configuration for use in the mobile power plant of the invention based on using multiple “mass market” charge controllers.

FIG. 4 shows an embodiment of an outline electrical configuration for use in the mobile power plant of the invention based on using a single specialist charge controller/inverter combined unit.

FIG. 5 shows an embodiment of an outline partial electrical configuration for use in the mobile power plant of the invention based upon the embedded “ribbon cable” concept.

FIG. 6 is a perspective view of an embodiment of the configuration of the charge controllers and inverter for use in the mobile power plant of the invention.

FIGS. 7 to 9 show an embodiment of the configuration of DC power cabling connectors and an end of the spool for use in the mobile power plant of the invention. FIG. 6 is a perspective view. FIG. 7 is a top-down view. FIG. 8 is a side-on view of the spool end without switch.

FIG. 10 is a cross-sectional view of an embodiment of a layered array structure with embedded DC power cabling for use in the mobile power plant of the invention.

FIG. 11 is a cross-sectional view of an embodiment of the array structure with embedded DC power cabling in the “ribbon cable” style and with the tension-bearing layer bonded to the lower side of the array structure for improved rolling behaviour.

FIGS. 12 to 13 show an embodiment of feeder arms and rollers. FIG. 12 is a perspective view. FIG. 13 is a cross-sectional view.

FIG. 14 is a perspective view of an embodiment of an inflatable support frame bonded to the lower side of the array structure.

FIG. 15 is a perspective view of an attachment means for the array structure to the top of military bastion boxes in order to provide a convenient and space-efficient deployment option.

### DETAILED DESCRIPTION

In the descriptions that follow, a 100 kW output 40 ft (12.2 m) container model is described as preferred. However, other lower outputs in smaller containers are also possible, and power outputs larger than 100 kW may also be possible within 40 ft (12.2 m) or even larger container sizes.

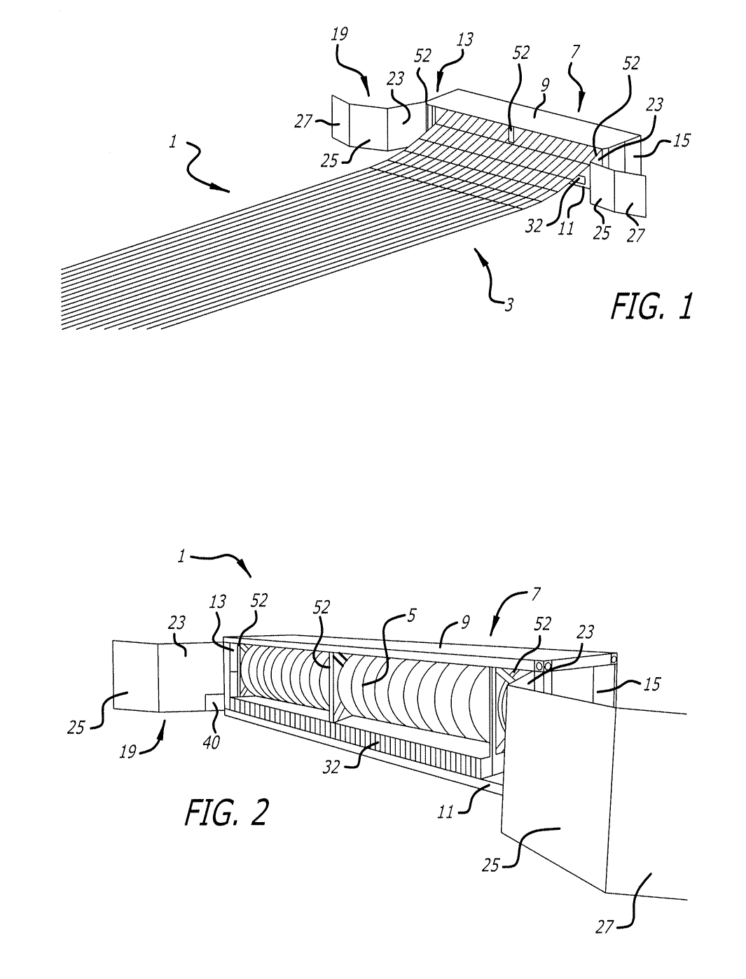

A key advantage of the mobile power plant 1 of the present invention is that the thin nature of the flexible array structure 3—both the PV panels (not labelled for clarity) and the substrate to which they are mounted—means that a very large length of PV panels can be stored rolled up 5 inside the container 7 (FIGS. 1, 2). For example, 50 m, 100 m or up to 200 m or more may be stored depending on the thickness of the array structure 3.

This presents a very large area of panel—up to 2000 m² in the case of a 40 ft (12.2 m) container 7. When stowed as shown in FIG. 2, the rolled array structure 5 fills the majority of the height of the container 7.

In the embodiment of FIG. 1, the container 7 comprises an upper 9, a lower 11 and two side walls 13, 15. There is also a rear wall 17 and a front section which has two doors 19, 21 that are shown open in this example. The doors 19, 21 of the embodiment of FIG. 1 have three segments: inner segments 23 connect to a side section 13, 15, middle segments 25 connect to inner segments 23, and outer segments 27 connect to middle segments 25. When the doors are closed, the outer segments 27 lie adjacent each other. Other door configurations are within the scope of the present disclosure.

In the unrolled or deployed configuration (FIG. 1), the doors 19, 21 of the container 7 are opened and the flexible array structure 3 is extended or deployed out from its rolled configuration 5 out of the container 7. In the fully rolled configuration 5, the doors 19, 21 of the container 7 may be closed without damaging the flexible array structure 3.

The flexible array structure 3 can be rolled around a spool 30. In some examples, the spool 30 is hollow. In some examples, the spool 30 is not hollow. In some examples, the spool 30 is not motorised. In some examples, the spool 30 is motorised.

A battery bank 32 is laid across the floor of the container 7, in order to spread the weight inside the container 7 and leave the greatest width available for the spool 30 and therefore for storable PV panels.

In a preferred example, at least enough battery capacity should be provided in order to maintain 30% of output for 24 hours. Based on the preferred 100 kW output unit in a 40 ft (12.2 m) container 7, this equates to 720 kWh of useable battery capacity.

Any suitable battery chemistry may be chosen. Due to the large amount of storage provided, preference may be given to those battery chemistries which provide an adequate energy density, deep discharge capability and long cycle life whilst still maintaining strong cost competitiveness. Therefore, as an example, lead acid (up to 50 wh/kg and 50% depth of discharge (DoD)) may not be preferred because the weight of the batteries would approach 29 tonnes (29,000 kg), which is in excess of the 40 ft (12.2 m) ISO container maximum net load of 26.5 tonnes (26,500 kg). As another example, advanced lithium ion batteries (of the Lithium Cobalt or Lithium Manganese type) may not be preferred from a cost perspective ($500 or more per kWh). Lithium iron phosphate or lithium yttrium iron phosphate batteries may provide an appropriate balance as they are cost competitive with lead acid batteries when an 80% DoD capacity has been accounted for, and they have an energy density of up to 90 wh/kg resulting in total battery weight of around 10 tonnes (10,000 kg). In some examples, a “Flow Battery” (a type of reversible fuel cell appropriate for large scale energy storage) could be used.

Even with batteries capable of very high charge-discharge efficiencies of 95% or more, large amounts of heat may be expected to be generated within the battery bank 32—perhaps around 5 to 7 kW of heating. The skilled person will therefore understand that cooling fans (not shown) may be preferred and in such cases the battery bank 32 should be structured in such a way as to leave air circulation gaps between cells, and have extraction fans and vents appropriately positioned so that the air flows evenly through all the cells within the battery bank. Similarly, cooling fans may be required to remove excess heat from the charge controllers and/or inverter.

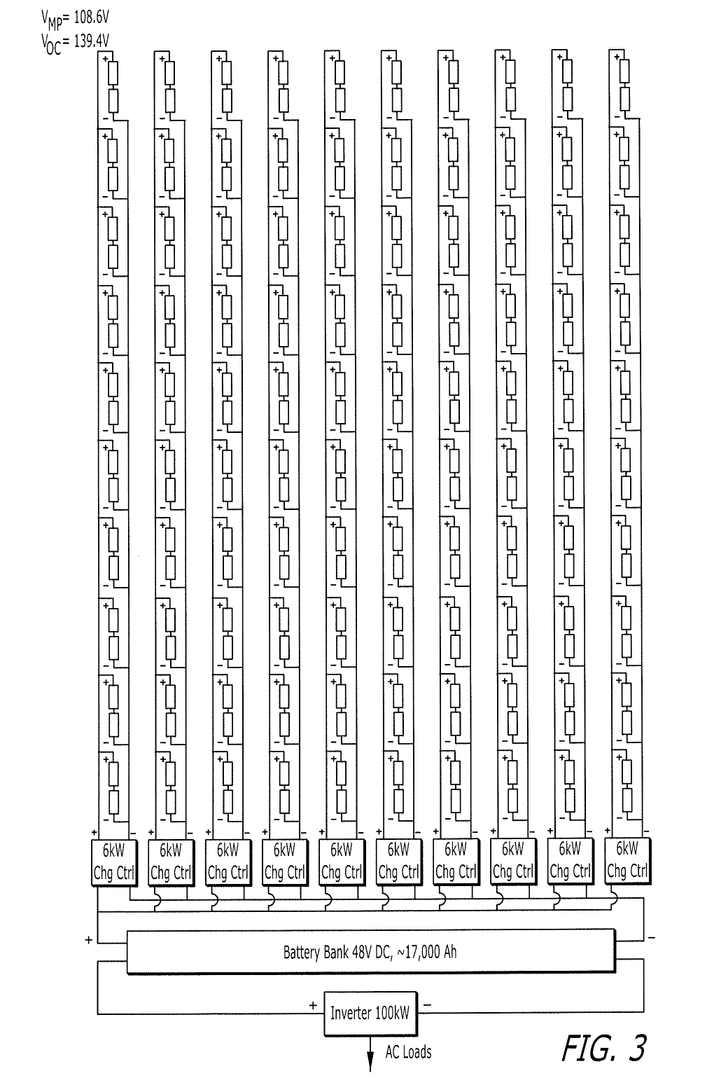

Three possible options for the electrical layout and connections between the panels are shown in FIGS. 3,4 and 5. There are many other combinations possible depending on the final charge controller, inverter,modules and embedded cable size selected, as will be clear to the skilled person on reading the present disclosure.

The first option is illustrated in FIG. 3, it is based on using a larger number of smaller-capacity charger controllers that are available on the retail market. The panels in this example are commercially available 300 W 12.6% efficiency thin-film panels with V_{∝}=69.7 V, V_{MPP,}=54.3 V and dimensions of 5.74×0.49 m. They are arranged in strings of two-series in parallel to maintain relatively low operating voltages consistent with mass-market products, and 20 panels in total to each row are shown. It will be understood that more or fewer panels may be used. The structure shown in FIG. 3 would be dimensioned around 120×5 m and produce 60 kWp. This would fit in a 20 ft. (6.1 m) shipping container—or doubled up for a 120 kWp 40 ft (12.2 m) container system as per the 100 kW output preference.

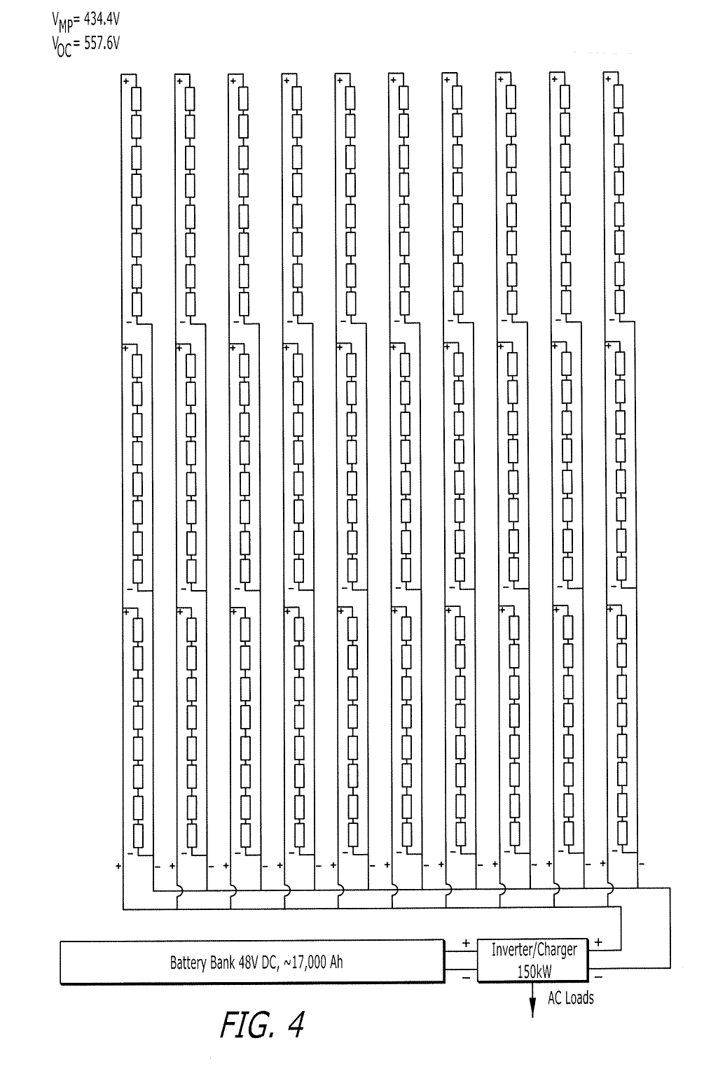

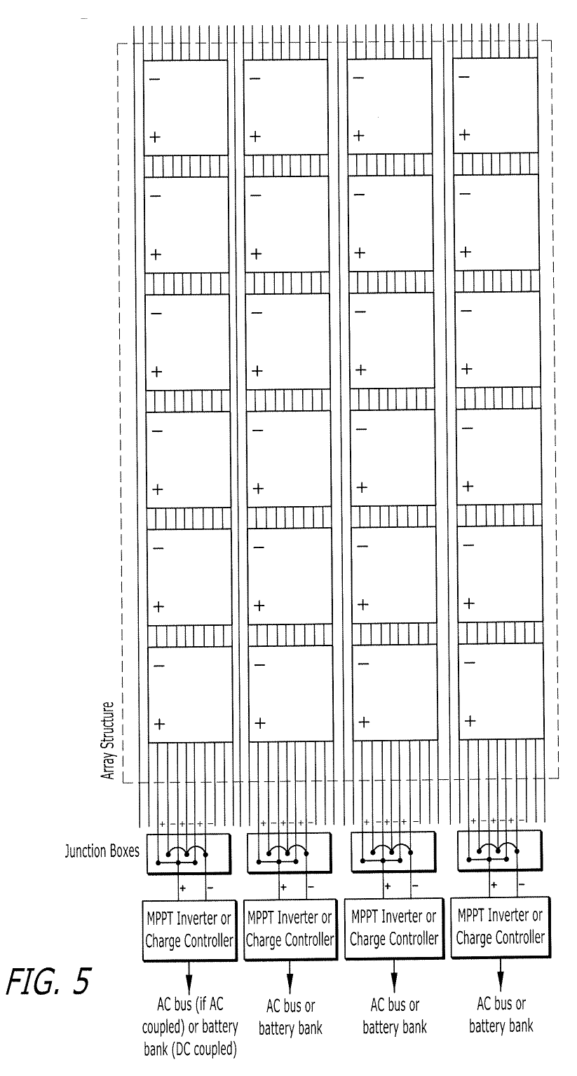

The second option is shown in FIG. 4. It is based on using a single specialist combined charge-controller/inverter unit. This option is preferable from the perspective of simplicity and reduction in cable losses, but may be less preferable than the previous example of FIG. 3 from the perspective of redundancy and resilience to failures. The panels for the example shown in FIG. 4 are the same as in FIG. 3, but arranged in strings of 8-series in parallel in order to leverage higher operating voltages (and hence lower power transmission losses on the DC power cabling) with 24 panels in total to each row. It will be understood that more or fewer panels may be used. The structure of FIG. 4 would be dimensioned around. 140×5 m and produce 72 kWp. ‘This would fit in a 20 ft (6.1 m) shipping container—or doubled up for a 144 kWp 40 ft 12.2 m) container system. The DC power-cabling within the array structure could, in this configuration, be combined into just two longitudinal cables running the length of the array structure. Due to the high current present in the cables in that scenario, the cables would have to be of a very large diameter in order to keep cable losses to an acceptable level. Therefore, in order to maintain the thinnest possible array structure (in which the power cabling could be integrated.), it may be preferable to have multiple cables of a thinner diameter as per the layout shown in FIG. 4, or increasing the number of cables yet further towards a “ribbon cable” configuration shown in FIG. 5.

FIG. 5 shows the third example—a partial detail (for the purposes of clarity) of the wiring illustrating the module connection concept in a “ribbon-cable” style configuration.

The number of parallel cable runs may be many more or less than that shown. Strings of 2 modules in series are shown with each string having dedicated cabling back to the junction boxes. Each of these strings can be considered as a subsection of the array. The example shows 3 longitudinal strings, although many more longitudinal strings may be present with cable-laying density higher than that illustrated. The example also illustrates how junction boxes (which may be located in the spool) may be used to parallel a number of strings together prior to connection to a dedicated inverter or charge controller to create a separately managed “modular” array supersection. For the purposes of clarity, longitudinal “modular” array supersections are shown, although in reality it may be advantageous to create lateral “modular” array supersections because this approach facilitates better performance under longitudinal shading variations—and additionally enables good performance if the array is only partially unrolled.

In this example the subsections are strings of modules connected in series. In other example modules may be connected in parallel to for a subsection.

In a typical example, a subsection may be about 100W-400W and a supersection might be about 2000W-8000W.

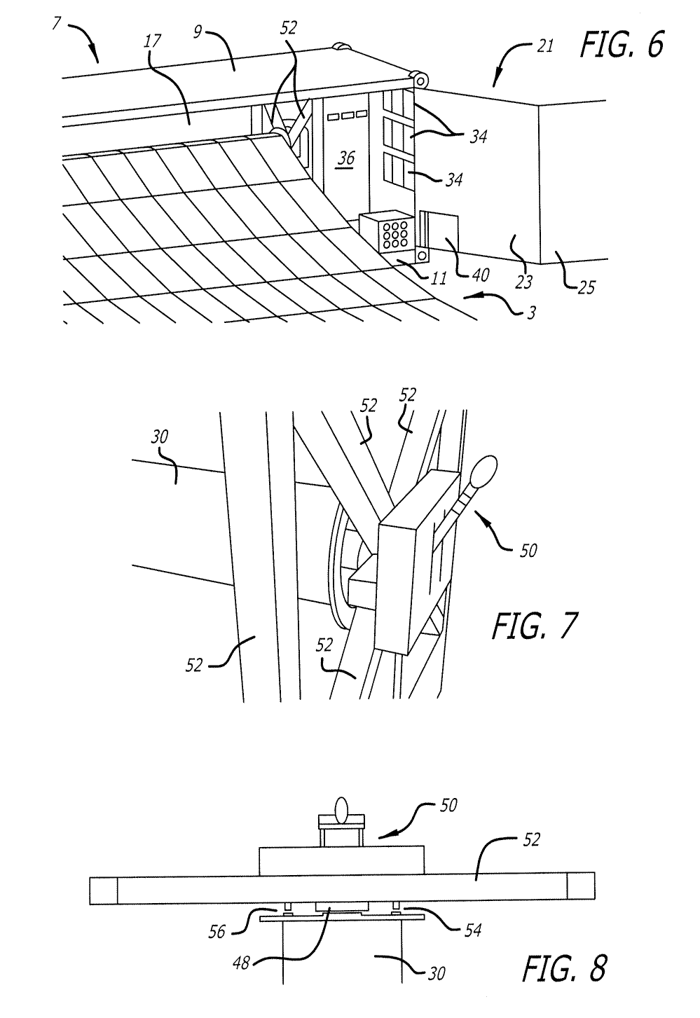

FIG. 6 illustrates an exemplary configuration within the container allowing the charge controllers 34 and inverter 36 to be housed. Depending on the option selected—e.g. if as shown in FIG. 3—multiple charge controllers 34 may be mounted on the rear wall 17 of the container 7 or, if a hollow spool 30 is used, within the hollow cylinder of the spool 30 itself (if the diameter allows). In the embodiment shown, nine charge controllers 34 are arranged in sets of three and mounted on the side wall 15, and the inverter 36 is against the back wall 17. FIG. 6 also shows the location of AC output sockets 38 and a hatch 40 built into a door 21 of the container 7 which could be used to access power from the power plant 1 when the flexible array structure 3 is in a stowed configuration and the container doors 19, 21 are closed.

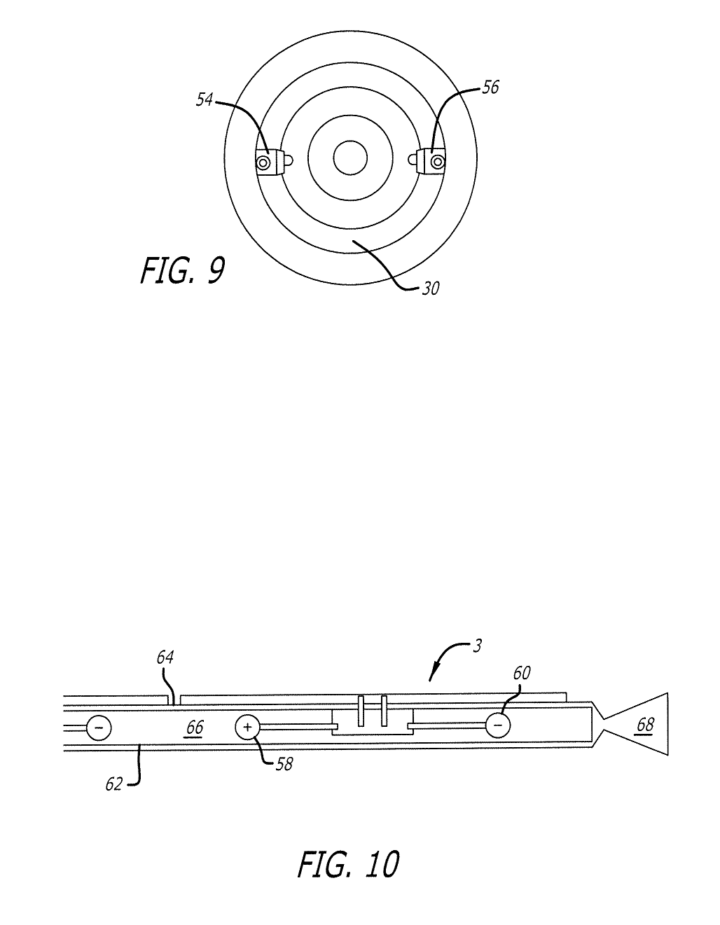

A preferred arrangement for connecting power cabling from within a rotatable spool 30 to fixed power cabling that runs to the charge controllers 34 is described with reference to FIGS. 7 to 9. Whilst rotating power connectors such as “slip ring” connectors are available for a permanent connection, in this example permanent connection is not necessary and such connectors, which have a high power rating, could be very expensive and incur additional losses compared with standard fixed connectors. It is therefore suggested in the preferred example that these connectors be fixed, with the intention that they should be connected once the flexible array structure 3 is deployed and disconnected before it is rolled up 5. In the event that the example outlined in FIG. 4 is chosen, a single two-pole high voltage connector would be required. In the example shown in FIG. 6, the connectors 54, 56 may be manually operated, as indicated by the switch 50. Alternatively it may be automated. A frame 52 is used to hold the spool 30 in position by means of a rotational bearing 48. In the present example, the frame 52 forms triangular portions for maximum strength. Other frame configurations may be employed. The rotating parts of the connectors 54, 56 may be mounted on the cylinder which forms the spool 30 (as shown in FIG. 8). A mechanical or electrically controlled system would stop the spool 30 rotating once sufficiently deployed and with the connectors 54, 56 in an aligned position. Additional DC isolation switches may be required in order to prevent or minimise arcing at the connectors as they are connected with the energised PV panels.

A solution to integrating the DC power cabling within the array structure 3 is shown in the cross-section view FIG. 10 (not to scale). The diameter of the DC cables 58, 60 must be kept moderate so that the array structure 3 is acceptably thin. The objective is to minimise the array structure thickness whilst maintaining strength, and in a preferred solution would need to be in the region of 1 to 2 cm or less. However, there is a compromise with cable losses. If necessary, multiple cable runs can be used as a substitute for higher diameter cabling. The thin layers 62, 64 shown below and above the central “filler” layer 66 are the main structural reinforcement, intended to take the tensile load as the array structure 3 is unrolled and to protect it from potential damage it could otherwise incur by being dragged over the ground. The bracket 68 fitted to the edge of the array structure 3 illustrates a preferred method for which the described “feeder arms” to grip the edges of the array structure 3.

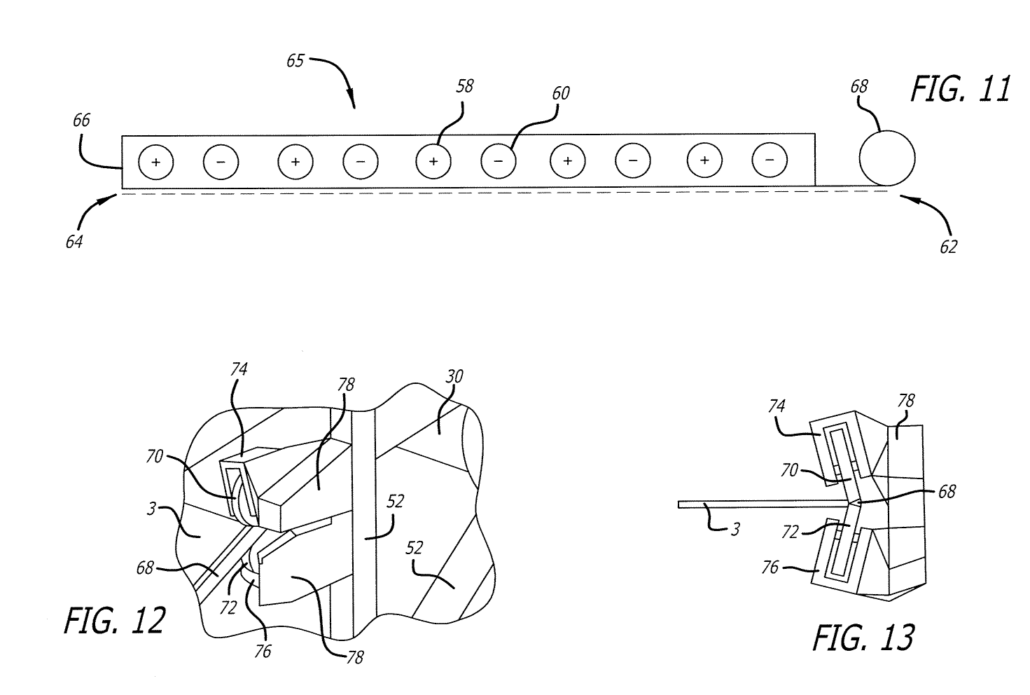

An alternative configuration of the array cross-section is shown in FIG. 11 (not to scale). Many more DC power cables 58, 60, are provided in a “ribbon cable” format which reduces the thickness of the cabling layer. Because it is sufficiently thin, the filler layer 66 may consist of an adhesive. The tension-bearing layer 64 is shown below the filler layer 66, so that it may be pre-tensioned for the purposes of improving rolling behaviour through encouraging compression of the lower surface during rolling. The protective layer 62 is shown bonded to the underside of the tension-bearing layer 64. The PV modules 65 are shown bonded directly to the filler layer 66. The “bracket” 68 is shown as a circular cross-section - in the form, for example, of a “kader” pole, bonded to the tension-bearing layer as the primary means through which support loads should be carried.

FIGS. 12 and 13 illustrate a preferred example of the “feeder arms”, with rollers 70, 72 which grip the bracket 68 and provide lateral bracing to prevent the array structure 3 from being off-centre when it is rolled back in. This could happen if, for example, it had been unrolled at a slight angle to perpendicular to the spool 30 where the deployment was done either by hand (for small models) or using a tow vehicle (for the larger models as per a preferred solution mentioned here). In the present embodiment, the rollers 70, 72 are arranged one above the other and are each mounted in a housing 74, 76 which is attached to a larger structure 78 which holds the rollers 70, 72 in place relative to the spool 30. The skilled person will understand that the structure 78 may take other forms.

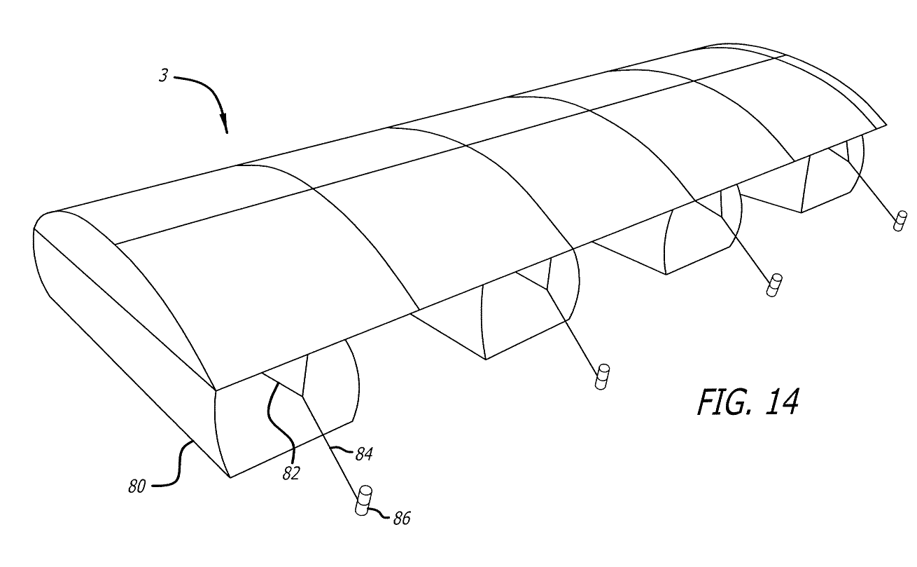

FIG. 14 illustrates an exemplary configuration of the inflatable support frame integrated into the lower side of the PV array structure. A series of inflatable chambers 80 are shown bonded to and supporting the PV array structure 3, in this example shown with gaps between for air circulation. The upper edges of the chambers have a curved shape so that the array structure 3 assumes the curvature shown when the chambers are inflated, which may be advantageous for rainfall runoff/drainage and sand/dust shedding. Load-spreading tabs 82 are shown connecting the array structure 3 to guy ropes 84, secured to the ground under tension by ground pegs 86. This fixing method keeps the array structure under tension and strongly secured to the ground. Other methods of fixing to the ground are possible, such as by using water ballast, sand bags or other weight-secured or surface attachment methods.

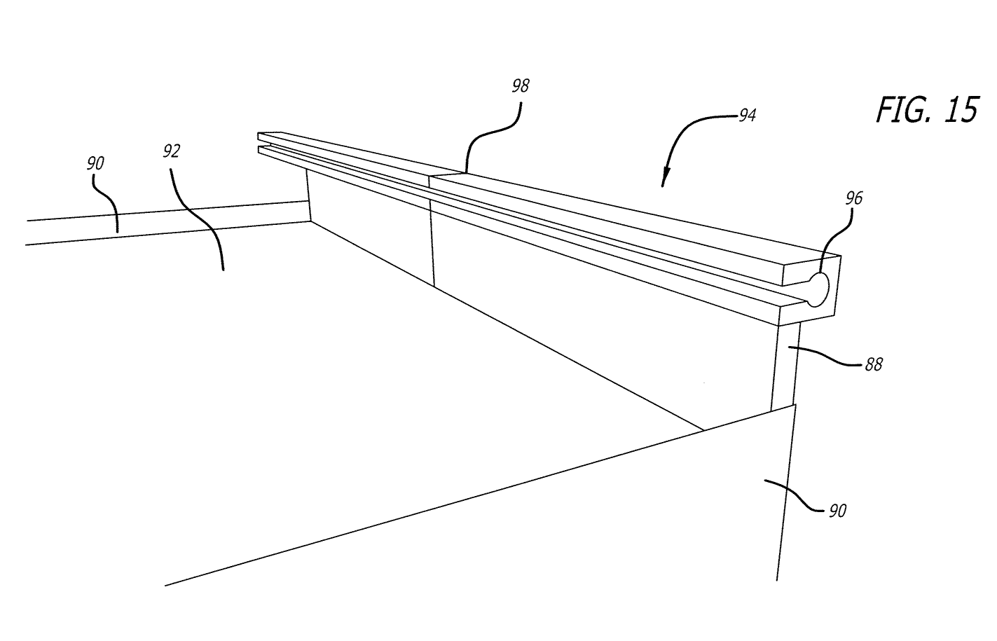

FIG. 15 illustrates an exemplary configuration of the attachment means of the array structure to the top of the bastion boxes. An extended section 88 to the bastion walls 90 is present on a side of the bastion box. The bastion box is shown filled with ballast 92. The extended section 88 secures a “kader” slot frame 94 with a circular cross-section 96 through which the array structure bracket/kader pole 68 may slide during deployment of the array. The extended section 88 and “kader” slot frame 94 may be split into two pieces at the center 98 in order that it may fold in a collapsible fashion along with the bastion box (which is typically provided as an unfolding unit). The “kader” slot frame 94 may be joined either permanently or removably with the “kader” slot frame of an adjacent bastion box, in order to create a continuous kader slot through which the array structure bracket 68 may slide. Such a configuration may be applied on just one side of the bastion box so that two rows of bastion boxes may be laid side-by-side with the “kader” slots 96 facing each other in order to create the required frame. Alternatively, such a configuration may be applied to opposing sides of the same bastion box so that a single row of bastion boxes may be used as the frame.

The “performance” figures noted in the above preferred example are based on currently commercially available and relatively inexpensive flexible PV panels with an efficiency of 12.6% producing around 106 W/m². There is much greater potential for efficiency improvement in thin-film panels such as CIGS, GaAs, CdTe and organic dye-based cells, as these are still in the early stages of commercialisation and. optimisation continues to yield percentage gains. Alta Devices, for example, has already achieved 28.8% efficiency in their GaAs cells, potentially resulting in 240 W/m² or more. Whilst these panels are currently very expensive, their use in the power plant of the present invention may provide a unit producing in excess of 300 kWp. With further optimisation with as thin and strong as possible a substrate this may approach 500 kWp. The trend of improved efficiencies and reducing costs of thin-film solar cell technology is likely to lead to further strengthening of the present invention in the future.

In addition to the above, a number of other features may be considered important in the potential markets available to this invention. A first example is integration into a wider area grid or a localized power grid (a “micro-grid”). Whilst the power plant of the invention is capable of performing as a stand-alone off-grid energy source, it may be preferred to operate it in conjunction with other sources of energy, preferably with other renewable sources of energy, such as wind-turbines, hydro power or the wider grid. There is presently an increased focus on enabling micro-grid technologies such as so-called “smart grid” control systems which collect data from grid-connected generators or loads and manage the balance of power generation and demand.

Accordingly, the power plant of the invention may be provided with a grid-synchronous AC-inverter so that it may be connected to a grid with which to share its power output. In addition to sharing its power output, it may be advantageous for a “smart-grid” to have control over energy storage facilities and to be able to feed excess power to them when necessary. Accordingly, the system of the invention may be provided with a power connection to receive power from an external source to charge the batteries included in the mobile power plant. This feature may be particularly helpful, for example, when an energy source such as a wind turbine elsewhere in the grid is generating at high output, but the mobile power plant is not due to high cloud cover or during the night. In this case, the mobile power plant could still receive a full battery charge and the excess power from the wind turbine would not be wasted. In order to enable this level of control by a smart-grid management system, electronics systems which control and/or limit the charge state and power output of the mobile power plant may be used, and/or telecommunications systems (which may be LAN, WiFi, cellular data or other form of data network connection) to enable the feedback of data and receipt of control commands. These methods may be implemented using products of existing “smart-grid” control systems or as per a published industry standard for such methods.

A second additional feature that may be considered of importance is the inclusion of a secondary backup power source such as a diesel generator or fuel cell with the mobile power plant of the invention. This may be particularly useful in locations of variable solar irradiance, so that backup power can be provided beyond the capacity of the included battery bank on the occasion of particularly bad weather for generation of solar energy. A diesel generator may be preferable from a cost perspective, and may be deployed in a hybrid model by being sized at the projected average power consumption and used to charge the batteries when instantaneous consumption is less than the generator power output (plus any remaining PV output). The battery backup then acts to meet any excess of demand above the generator output. This approach may result in overall greater efficiency than using a generator sized at the maximum power of the mobile power plant of the invention running at full power continuously.

A third additional feature is an apparatus for use in a method of inclining the solar array structure towards the sun for use in higher latitudes where the correct panel angle can result in significant percentage power output gains. One way to achieve this would be to deploy the array structure on an appropriate south-facing slope (or north facing in the southern hemisphere) of approximately the correct angle. However, there may be many occasions when the system must be deployed on flat land or where an appropriate slope is not available. Therefore, a system of support poles and guy ropes may be used to raise one side edge of the array structure once deployed. The poles may be of adjustable length in order to set the correct angle, and may fit into rings or other attachment points on at least one edge of the flexible array structure. Guy ropes and ground pegs may be used to secure the poles in position and to secure the opposite edge to the ground. The tension-bearing substrate within the array structure may be particularly useful in such a scenario.

A fourth additional feature is related to military requirements for protection against Electromagnetic Pulse (EMP) events. These EMP events may be caused by lightning strikes or by high-altitude nuclear detonations and they have the effect of causing instantaneous and damaging current and voltage surges in electrical equipment. Whilst the array structure was stowed, including appropriate mesh screening to form a Faraday Cage around the container may be suitable. This could also function to provide some protection to the electronic components inside the container even whilst the array structure is deployed, by extending the mesh into the weather-protective screen previously mentioned, this sealing closely up against the array structure. However in this scenario, strong voltage/current surges may still arrive through the DC power cabling of the array structure, so high performance surge protectors and/or fuses may be required to isolate any incoming surge that has been created in the array structure and protect the components in the container. One option for protecting the array structure while deployed may be to encase the entire array structure in a wire mesh. This may cause significant performance reduction of the solar panels.

A fifth additional feature, also related to military requirements, concerns protection against ‘conventional’ attack. A necessary thickness of armour may be included in the container walls for protection of the mobile power plant whilst stowed against small arms fire, RPGs, IEDs or similar threats. This may also provide some level of protection for the components in the container even whilst it is deployed. The resilience question is important in this case in regards to the array structure. So, this may be another reason why multiple lines of DC power cabling may be preferable (see above discussion), so that an impact could be received on one side of the array structure (perhaps knocking out a single line of panels)—but the rest can continue generating power.

The skilled person will appreciate that modifications to the above-described examples may be made that fall within the scope of the invention. The scope of the invention is defined by the claims.

1. A mobile power plant comprising:
a flexible solar panel structure comprising a plurality of thin film photovoltaic panels mounted on a flexible substrate, the flexible substrate comprising a layered structure;
a spool attached to a portion of the flexible solar panel structure and around which the flexible solar panel structure can be rolled;
insulated power cabling integrated into the layered structure of the flexible substrate extending along a length direction of the flexible solar panel structure, wherein at least some of the insulated power cabling transmits power from the plurality of thin film photovoltaic panels to a spool-end of the flexible solar panel structure using a parallel connection,
a transportable container in which the spool is mounted, the transportable container being capable of housing the flexible solar panel structure when it is in a rolled configuration.

2. A mobile power plant according to claim 1, having a battery bank and charge controllers for storing energy generated by the flexible solar panel structure.

3. A mobile power plant according to claim 1, having an inverter for transferring power from the flexible solar panel structure or battery bank to output AC power.

4. A mobile power plant according to claim 1, wherein the layered structure of the flexible substrate a tension-bearing substrate layer onto which the thin film photovoltaic panels are mounted, the tension-bearing substrate layer being capable of bearing a tensile stress imposed on the flexible solar panel structure when it is unrolled.

5. A mobile power plant according to claim 1, wherein the transportable container is an ISO standard shipping container.

6. A mobile power plant according to claim 2, comprising a power connection configured to receive power from an external source to charge a battery bank of the mobile power plant to enable integration into a grid, the power connection being capable of being implemented as required by an existing smart-grid control system or smart grid industry standard.

7. A mobile power plant according to claim 1, comprising an electronics system configured to control and/or limit a charge state, power output, or other relevant properties of the mobile power plant to enable integration into a grid, the electronics system being capable of being implemented as required by an existing smart-grid control system or smart grid industry standard.

8. A mobile power plant according to claim 1, comprising a telecommunications system configured to enable control of relevant properties of the mobile power plant to be carried out remotely by a human operator or by a computer system, the telecommunications system being capable of being implemented as required by an existing smart-grid control system or smart grid industry standard.

9. A mobile power plant according to claim 1, including a secondary backup power source and/or secondary energy storage module.

10. A mobile power plant according to claim 9, wherein the secondary backup power source includes one or more of a diesel generator, a fuel cell, and a hydrogen generator.

11. A mobile power plant according to claim 1, having a series of support poles and guy ropes capable of raising one side edge of the flexible panel structure once deployed, in order to incline it towards the sun.

12. A mobile power plant according to claim 2, having retractable high power DC connectors between the spool and the charge controllers, so that in use the power cabling received at the rotating spool can be connected to fixed power cables that connect to the charge controllers and/or an inverter.

13. A mobile power plant according claim 1, wherein the flexible substrate comprises a layered structure, the power cabling being integrated into a single layer of the flexible substrate.

14. A mobile power plant according to claim 1, wherein the flexible substrate comprises a layered structure that includes a layer of protective backing material on the flexible solar panel structure.

15. A mobile power plant according to claim 1, wherein the flexible substrate comprises a layered structure that includes an environmental sealing coating for preventing environmental damage to the flexible solar panel structure.

16. A mobile power plant according to claim 1, having one or more feeder arms, the one or more feeder arms being capable of guiding the flexible panel structure into the transportable container.

17. A mobile power plant according to claim 1, with a retractable weather-protective screen to at least partially cover an openable side of the container from which the panel structure may extend in use.

18. A mobile power plant according to claim 17, wherein a lower part of the screen has a brush or sweeper edge which is capable of removing attached debris from the lower side of the flexible panel structure during retraction or deployment of the flexible panel structure.

19. A mobile power plant according to claim 1, wherein the spool is motorized.

20. A mobile power plant according to claim 1, comprising a grid-synchronous AC inverter to enable integration into a grid.

21. A mobile power plant according to claim 1, wherein protection is provided against Electromagnetic Pulse (EMP) attack or lightning strike, the protection comprising mesh screening to form a Faraday Cage around the transportable container, the mesh screening being attached to the walls of the transportable container.

22. A mobile power plant according to claim 1, wherein protection is provided against Electromagnetic Pulse (EMP) attack or lightning strike, the protection comprising surge protectors at the point of connection of the incoming power cabling from the panel structure to isolate any incoming surge that has been created in the panel structure and protect the components in the container.

23. A mobile power plant according to claim 22, wherein the mesh screening is attached to the walls of the transportable container and the weather-protective screen.

24. A mobile power plant according to claim 23, where the container is armored, the armor being capable of providing protection against small arms fire, RPGs, and/or IEDs.
